(19) United States
(12) Patent Application Publication
(10) Pub. No.: US 2020/0313319 A1
(43) Pub. Date: Oct. 1, 2020

(54) LED LIGHTING DEVICE

(71) Applicant: XIAMEN ECO LIGHTING CO. LTD., Xiamen (CN)

(72) Inventors: liang liang Cao, Xiamen (CN); xiao bo Chen, Xiamen (CN); yun nan Lin, Xiamen (CN); ming hao Wu, Xiamen (CN)

(21) Appl. No.: 16/365,651

(22) Filed: Mar. 26, 2019

(51) Int. Cl. H01R 12/51; H01R 4/06; H05K 1/18; F21K 9/232; F21K 9/238

(52) U.S. Cl. CPC H01R 12/51; H01R 4/06; H05K 1/182; F21Y 2115/10; F21K 9/238; H05K 2201/09072; H05K 2201/10189; F21K 9/232

(57) ABSTRACT

An LED lighting device includes: a bulb shell; a light-source board having a connector, the light-source board disposed in the bulb shell for generating optical light; a conductive rivet disposed on a bottom of the LED light device; and a fusible resistor having a first conductive-line terminal clamped by the connector and a second conductive-line terminal coupled to the conductive rivet.

### BACKGROUND

With the development of technology, LED (Light Emitting Diode) products are more and more popular in lighting field. In this highly competitive market, how to reduce the cost of the LED products becomes an urgent problem in this field.

However, the above mentioned devices fail to modify their resistor R and the cement resistor respectively. In addition, during the manufacturing of the above mentioned devices, the devices are still assembled in parts, which may decrease the productivity and increase the cost of the devices.

### SUMMARY

The present invention relates to an LED lighting device, and more particularly to an LED lighting device manufactured by an automation process.

Embodiments of the present invention provide an LED lighting device. The LED lighting device comprises a bulb shell, a light-source board, a conductive rivet, and a fusible resistor. The light-source board has a connector, and the light-source board is disposed in the bulb shell for generating optical light. The conductive rivet is disposed on a bottom of the LED light device. The fusible resistor has a first conductive-line terminal clamped by the connector and a second conductive-line terminal coupled to the conductive rivet.

In one embodiment of the LED lighting device, the fusible resistor is orthogonally coupled to the light-source board.

In one embodiment of the LED lighting device, the connector comprises at least one metal spring disposed in a middle of the connector for clamping the first conductive-line terminal of the fusible resistor.

In one embodiment of the LED lighting device, the first conductive-line terminal and the second conductive-line terminal of the fusible resistor are formed by a first conductive line and a second conductive line respectively, and the first conductive line is shorter and harder than the second conductive line.

In one embodiment of the LED lighting device, the LED lighting device further comprises a lamp holder and a light bulb adapter. The lamp holder is arranged to hold the bulb shell. The light bulb adapter is installed on a bottom of the lamp holder. The conductive rivet is installed on a bottom of the light bulb adapter, and the fusible resistor penetrates the light bulb adapter and the lamp holder to reach the light-source board from the conductive rivet.

In one embodiment of the LED lighting device, the lamp holder comprises an intra-cavity connection configured to have a guiding column. The guiding column is arranged to axially cut-through the intra-cavity connection to form a guiding channel in the intra-cavity connection, and the fusible resistor is disposed in the guiding channel.

In one embodiment of the LED lighting device, the first conductive-line terminal of the fusible resistor is extended to protrude an end of the guiding channel for connecting the light-source board, the second conductive-line terminal of the fusible resistor is extended to protrude another end of the guiding channel for connecting the conductive rivet.

In one embodiment of the LED lighting device, the guiding channel comprises a resistor receiving chamber and a guiding chamber. The resistor receiving chamber is formed on a first end of the guiding channel that is faced to the light-source board. The guiding chamber is formed on a second end of the guiding channel that is faced to the conductive rivet, wherein a radial size of the resistor receiving chamber is greater than the guiding chamber, and a connecting boundary of the resistor receiving chamber and the guiding chamber forms a step.

In one embodiment of the LED lighting device, the fusible resistor further comprises a fusible element formed between the first conductive-line terminal and the second conductive-line terminal, the fusible element is disposed in the resistor receiving chamber, and the fusible element is attached on the step.

In one embodiment of the LED lighting device, the LED lighting device further comprises a metal cup embedded on an inner wall of the lamp holder for installing the light source board on the lamp holder, wherein an inner wall of the metal cup, which is above the light-source board, is riveted such that the metal cup is deformed for contacting a conductive layer of the light-source board.

In one embodiment of the LED lighting device, the connector comprises a pair of metal springs and a cut-through channel. The cut-through channel is formed along an inputting direction of the first conductive-line terminal of the fusible resistor, an end of the cut-through channel that is faced to the fusible resistor is arranged to have a guiding hole, and an exit of the guiding hole is faced to the pair of metal springs.

In one embodiment of the LED lighting device, an entry of the guiding hole that is faced to the fusible resistor is greater than the exit that is faced to the pair of metal springs.

In one embodiment of the LED lighting device, the pair of metal springs are a pair of opposite clamping metal springs, the first conductive-line terminal of the fusible resistor is clamped between the pair of opposite clamping metal springs for electrically connecting the light-source board.

In one embodiment of the LED lighting device, the pair of metal springs are disposed in the cut-through channel, a pair of first terminals of the pair of metal springs are fixed, a pair of second terminals of the pair of metal springs are arranged to extend oppositely to approach each other, a distance between the pair of metal springs is gradually decreased along the inputting direction of the first conductive-line terminal of the fusible resistor.

In one embodiment of the LED lighting device, the central axis of the guiding hole is aligned with a middle position between the metal springs.

Embodiments of the present invention provide an LED lighting device. The LED lighting device comprises a bulb shell, a light-source board, a lamp holder, a light bulb adapter, a conductive rivet, and a fusible resistor. The light-source board is disposed in the bulb shell for generating optical light. The lamp holder is arranged to hold the bulb shell. The light bulb adapter is installed on a bottom of the lamp holder. The conductive rivet is disposed on a bottom of the light bulb adapter. The fusible resistor is penetrated the light bulb adapter and the conductive rivet to electrically connect the light-source board and the conductive rivet.

In one embodiment of the LED lighting device, the fusible resistor comprises a fusible element, a first conductive line, and a second conductive line. The first conductive line is connected to a first terminal of the fusible element. The second conductive line is connected to a second terminal of the fusible element. The first conductive line and the second conductive line have different lengths.

In one embodiment of the LED lighting device, the first conductive line is connected to the light-source board, the second conductive line is connected to the conductive rivet, and a first length of the first conductive line is shorter than a second length of the second conductive line.

In one embodiment of the LED lighting device, the lamp holder comprises an intra-cavity connection arranged to have a guiding column; wherein the guiding column is arranged to axially cut-through the intra-cavity connection to form a guiding channel in the intra-cavity connection, and the fusible resistor is disposed in the guiding channel.

In one embodiment of the LED lighting device, the guiding channel comprises a resistor receiving chamber and a guiding chamber. The resistor receiving chamber is formed on a first end of the guiding channel that is faced to the light-source board. The guiding chamber is formed on a second end of the guiding channel that is faced to the conductive rivet; wherein a radial size of the resistor receiving chamber is greater than the guiding chamber, and a connecting boundary of the resistor receiving chamber and the guiding chamber forms a step for attaching the fusible element.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram illustrating a cross-sectional view of an LED lighting device in accordance with some embodiments.

FIG. 2 is a diagram illustrating an exploded view of an LED lighting device in accordance with some embodiments.

FIG. 3 is a diagram illustrating a light-source board, a lamp holder, and a light bulb adapter of an LED lighting device in accordance with some embodiments.

FIG. 4 is a diagram illustrating a cross-sectional view of a connector of an LED lighting device in accordance with some embodiments.

FIG. 5 is a diagram illustrating a bottom view of a connector of an LED lighting device in accordance with some embodiments.

FIG. 6 is a diagram illustrating a top view of a connector of an LED lighting device in accordance with some embodiments.

FIG. 7 is a diagram illustrating a riveting punch riveting an inner wall of a metal cup in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the standard deviation found in the respective testing measurements. Also, as used herein, the term “about” generally means within 10%, 5%, 1%, or 0.5% of a given value or range. Alternatively, the term “about” means within an acceptable standard error of the mean when considered by one of ordinary skill in the art. Other than in the operating/working examples, or unless otherwise expressly specified, all of the numerical ranges, amounts, values and percentages such as those for quantities of materials, durations of times, temperatures, operating conditions, ratios of amounts, and the likes thereof disclosed herein should be understood as modified in all instances by the term “about”. Accordingly, unless indicated to the contrary, the numerical parameters set forth in the present disclosure and attached claims are approximations that can vary as desired. At the very least, each numerical parameter should at least be construed in light of the number of reported significant digits and by applying ordinary rounding techniques. Ranges can be expressed herein as from one end point to another end point or between two end points. All ranges disclosed herein are inclusive of the end points, unless specified otherwise.

One of the purposes of the present embodiments is to solve the problem of high production cost due to the large number of components and complicated assembly process of the LED (Light Emitting Diode) lighting device. Therefore, in the present invention, the LED lighting device has relatively less number of components and the components are assembled by various automation processes.

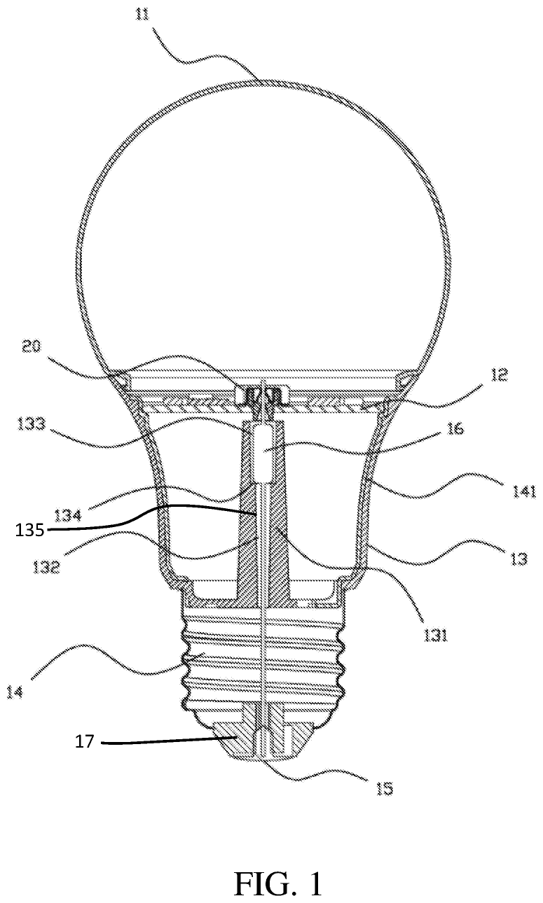

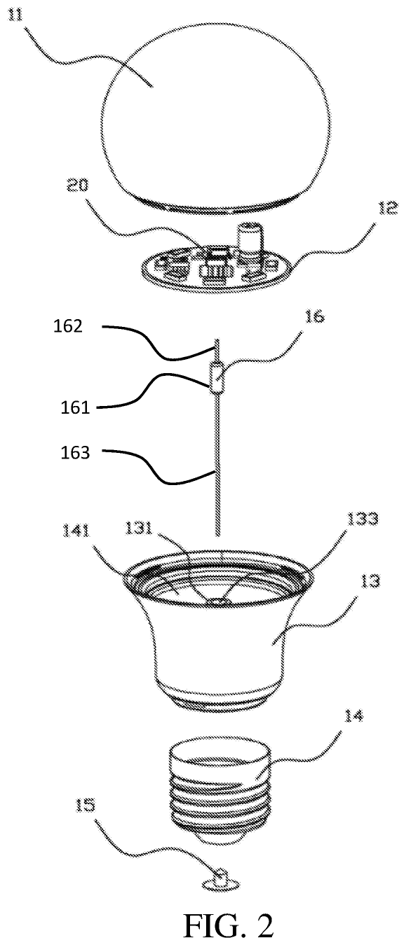

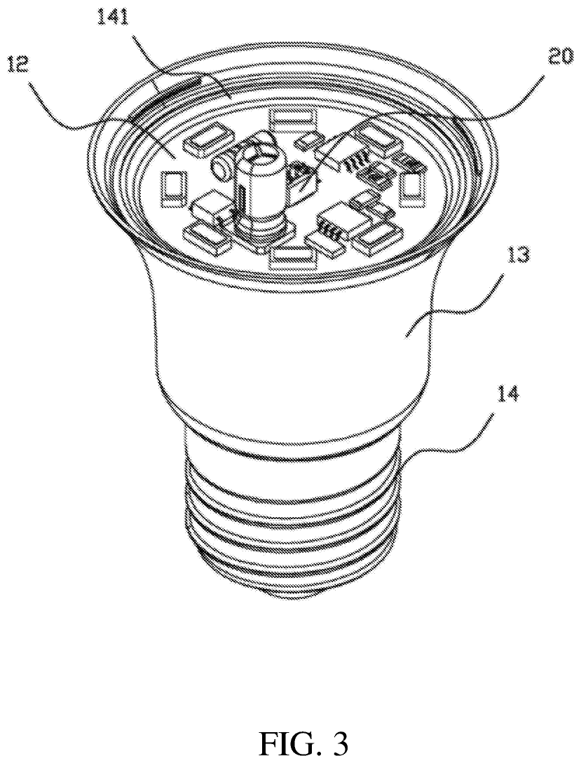

According to some embodiments, the presented LED lighting device is shown in FIG. 1, FIG. 2, and FIG. 3. FIG. 1 is a diagram illustrating a cross-sectional view of a LED lighting device in accordance with some embodiments. FIG. 2 is a diagram illustrating an exploded view of the LED lighting device in accordance with some embodiments. FIG. 3 is a diagram illustrating a light-source board, a lamp holder, and a light bulb adapter of the LED lighting device in accordance with some embodiments.

According to some embodiments, the LED lighting device comprises a bulb shell 11, a light-source board 12, a lamp holder 13, a light bulb adapter 14, a conductive rivet 15, and a fusible resistor 16. The light-source board 12 is installed/disposed in the bulb shell 11 for generating optical light. Specifically, the light-source board 12 is installed on one end (e.g. the top side) of the lamp holder 13, and the light bulb adapter 14 is installed on the other end (e.g. the bottom side) of the lamp holder 13. The conductive rivet 15 is disposed on the bottom of the light bulb adapter 14. However, the conductive rivet 15 is insulated from the bottom of the light bulb adapter 14. For example, an insulating device 17 is formed between the conductive rivet 15 and the light bulb adapter 14.

According to some embodiments, as shown in FIG. 1 and FIG. 2, the fusible resistor 16 is orthogonally coupled to the light-source board 12. The fusible resistor 16 comprises a fusible element 161, a first conductive-line terminal 162, and a second conductive-line terminal 163. The first conductive-line terminal 162 and the second conductive-line terminal 163 have different lengths. The first conductive-line terminal 162 and the second conductive-line terminal 163 of the fusible resistor 16 are formed by a first conductive line and a second conductive line respectively, and the first conductive line is shorter and harder than the second conductive line. In this embodiment, the first conductive-line terminal 162 is connected to the light-source board 12, the second conductive-line terminal 163 is connected to the conductive rivet 15, and the length of the first conductive-line terminal 162 is shorter than the second conductive-line terminal 163.

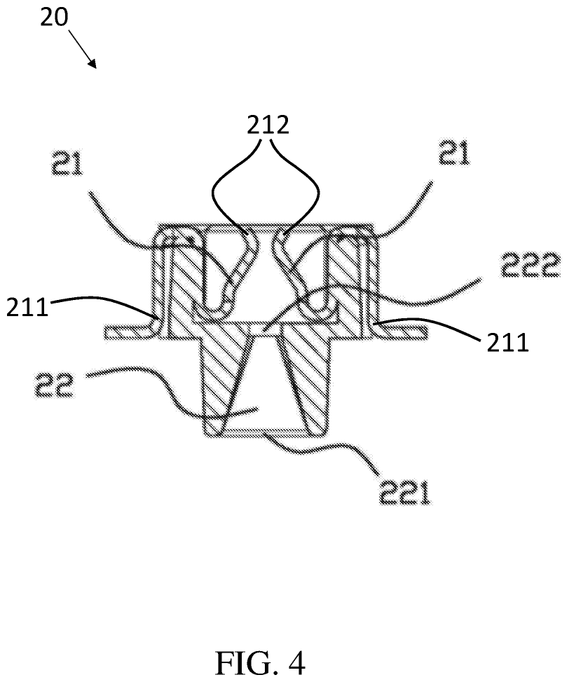

The bulb shell 11 is arranged to cover the top of the lamp holder 13 to form the whole structure of the LED lighting device. Inside the LED lighting device, the light-source board 12 and the conductive rivet 15 are connected to the two terminals of the fusible resistor 16 respectively. A connector 20 is formed on the light-source board 12, the connector 20 is electrically connected to the functional circuits on the light-source board 12, and the connector 20 is arranged to clamp the first conductive-line terminal 162 of the fusible resistor 16 by using a pair of metal springs. The pair of metal springs (i.e. 21) are disposed in the middle of the connector 20 as shown in FIG. 4 below.

According to some embodiments, the fusible resistor 16 is installed along the central axis of the lamp holder 13 and along the central axis of the light bulb adapter 14. More specifically, the fusible resistor 16 is directly connected from the conductive rivet 15 to the light-source board 12. In other words, the fusible resistor 16 penetrates the light bulb adapter 14 and the lamp holder 13. By doing this, the conductive lines (i.e. 162 and 163) on the two terminals of the fusible resistor 16 may not be skewed during the assembly process. Moreover, if the conductive rivet 15 is too long or too high, the conductive rivet 15 may not tilt, and the problem of short circuit may be avoided. According to some embodiments, a guiding column 131 is formed on an intra-cavity connection of the lamp holder 13, the guiding column 131 corresponding to the fusible resistor 16 is disposed on the central axis of the lamp holder 13. The guiding column 131 and the lamp holder 13 may be formed as a one-piece device. The guiding column 131 is arranged to axially cut-through to form a guiding channel 132 therein, the fusible resistor 16 is installed in the guiding channel 132, and the first conductive-line terminal 162 of the fusible resistor 16 is extended to protrude an end (e.g. the top) of the guiding channel 132 for connecting the light-source board 12. The conductive-line terminal 163 of the fusible resistor 16 is extended to protrude the other end (e.g. the bottom) of the guiding channel 132 for connecting the conductive rivet 15.

The guiding channel 132 comprises a resistor receiving chamber 133 and a guiding chamber 135. The resistor receiving chamber 133 is formed on a first end (e.g. upper portion) of the guiding channel 132 that is faced to the light-source board 12. The guiding chamber 135 is formed on a second end (e.g. the lower portion) of the guiding channel 132 that is faced to the conductive rivet 15.

The resistor receiving chamber 133 is arranged to accommodate the fusible element 161 of the fusible resistor 16. The guiding chamber 135 is arranged to accommodate a portion (e.g. the upper portion) of the conductive-line terminal 163 of the fusible resistor 16.

As the diameter of the fusible element 161 of the fusible resistor 16 is greater than the diameters of the conductive-line terminals 162 and 163, the radial size of the resistor receiving chamber 133 is greater than the guiding chamber 135. When the radial size of the resistor receiving chamber 133 is greater than the guiding chamber 135, and a connecting boundary of the resistor receiving chamber 133 and the guiding chamber 135 forms a step (or a stage) 134. When the fusible element 161 of the fusible resistor 16 is accommodated in the resistor receiving chamber 133, the fusible element 161 may be attached or held by step 134. The resistor receiving chamber 133 may restrict the horizontal movement of the fusible element 161. When the conductive rivet 15 is firmly connected with the conductive-line terminal 163 of the fusible resistor 16, the pulling effect caused by the conductive rivet 15 may indirectly force the fusible element 161 to further attach on the step 134. Accordingly, the fusible element 161 of the fusible resistor 16 may be firmly fixed inside the resistor receiving chamber 133, and the reliability of assembling process is improved.

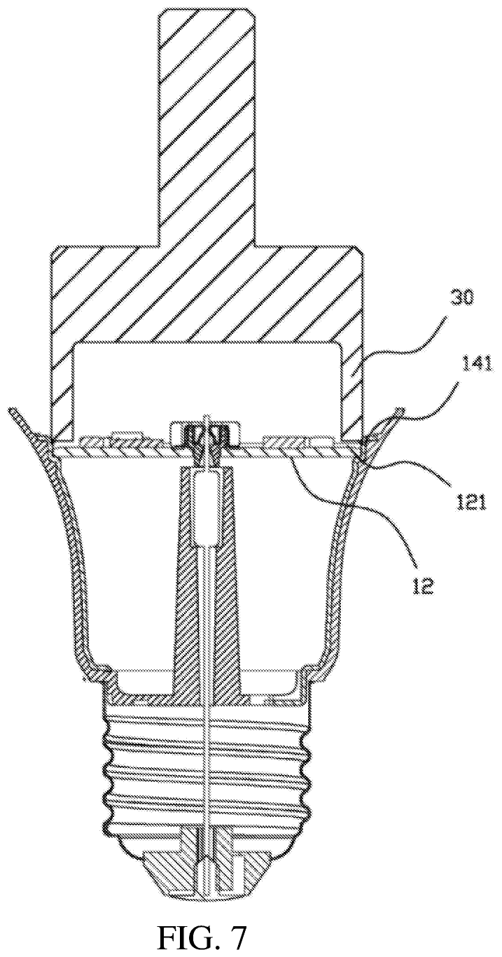

In order to manufacture the LED lighting device by an automation assembling process, the wielding process of conductive lines is omitted in the assembly process. The presented assembly process is mostly accomplished by mechanical operation. More specifically, to avoid the wielding process in the assembly process, the metal cup 141 is embedded or mounted on the inner wall of the lamp holder 13 for installing the light-source board 12 on the lamp holder 13. During the assembly process, a riveting punch (e.g. the riveting punch 30 in FIG. 7) is used for riveting the inner wall, which is higher than the light-source board 12, of the metal cup 141 such that the metal cup 141 is deformed to contact or electrically connect the conductive layer 121 of the light-source board 12. Accordingly, the conductive rivet 15, the fusible resistor 16, the light-source board 12, and the metal cup 141 may be electrically connected with each other. Due to the physical contact between the metal cup 141 and the conductive layer 121 (e.g. copper foil) of the light-source board 12, the metal cup 141 and the conductive layer 121 of the light-source board 12 are electrically connected with each other. Accordingly, the assembling process may be simplified, and the productivity is increased. Moreover, the metal cup 141 is not only used as an electrode of the LED lighting device, the metal cup 141 may also be used to dissipate heat generated by the LED lighting device. Therefore, the heat sink of the LED lighting device may be omitted. According to the embodiment of the light-source board 12, the functional components are mainly formed in the middle of the light-source board 12 while the illuminating modules are distributed on the periphery of the light-source board 12.

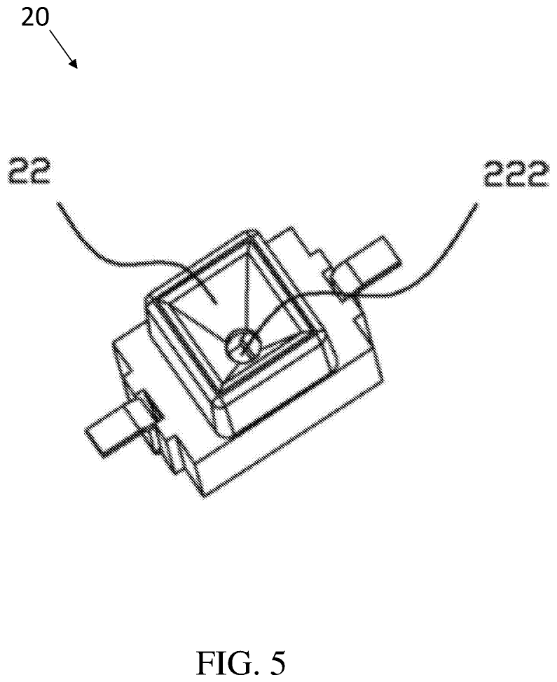

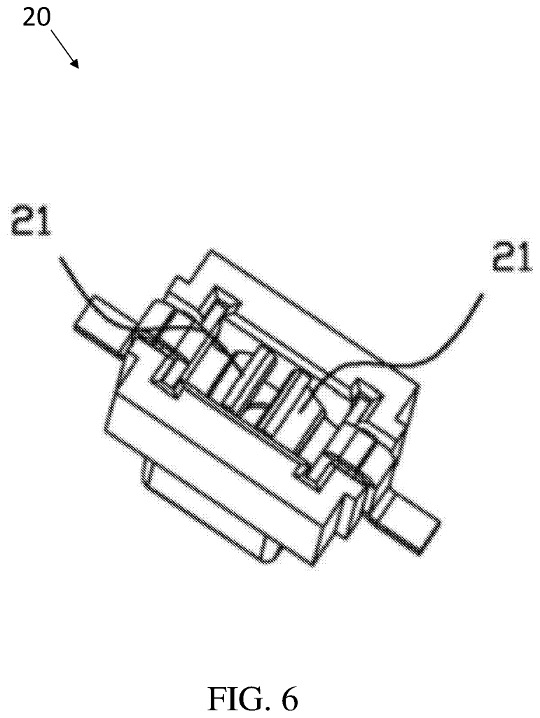

FIG. 4 is a diagram illustrating a cross-sectional view of the connector 20 of the LED lighting device in accordance with some embodiments. FIG. 5 is a diagram illustrating a bottom view of the connector 20 f the LED lighting device in accordance with some embodiments. FIG. 6 is a diagram illustrating a top view of the connector 20 of the LED lighting device in accordance with some embodiments. According to some embodiments as shown in FIG. 4, FIG. 5, and FIG. 6, the connector 20 is arranged to form a cut-through channel along an inputting direction of the conductive-line terminal 162 of the fusible resistor 16. To make the conductive-line terminal 162 of the fusible resistor 16 to be easily inserted or plugged into the cut-through channel, an end of the cut-through channel that is faced to the conductive-line terminal 162 of the fusible resistor 16 is arranged to have a guiding hole 22, wherein an exit 222 of the guiding hole 22 is faced to a pair of metal springs 21. Moreover, an entry 221 of the guiding hole 22 that is faced to the fusible resistor 16 is greater than the exit 222 that is faced to the metal springs 21. During the plug-in operation, when the conductive-line terminal 162 of the fusible resistor 16 is placed within the range of the guiding hole 22, the guiding hole 22 may guide the conductive-line terminal 162 of the fusible resistor 16 to output the exit 222 of the guiding hole 22. The conductive-line terminal 162 of the fusible resistor 16 may enter the clamping area between the pair of metal springs 21. Then, the conductive-line terminal 162 of the fusible resistor 16 may be clamped by the metal springs 21.

According to some embodiments, the connector 20 is configured to comprise a pair of opposite clamping metal springs 21, the conductive-line terminal 162 of the fusible resistor 16 is clamped between the pair of opposite clamping metal springs 21 for electrically connecting the fusible resistor 16 to the light-source board 12. Accordingly, the conductive rivet 15 and the light-source board 12 may be electrically connected with each other.

As the fusible resistor 16 is disposed between the light-source board 12 and the conductive rivet 15, the conductive-line terminal 162 of the fusible resistor 16 is plugged or inserted into the connector 20 from the bottom of the light-source board 12. The metal springs 21 are disposed in the cut-through channel. A pair of first terminals 211 of the metal springs 21 may be fixed on the housing of the connector 20, and a pair of second terminals 212 of the metal springs 21 are configured to extend in opposite directions in order to approach each other. According to some embodiments, the pair of first terminals 211 of the metal springs 21 may be electrically connected to the circuits of the light-source board 12.

In addition, to increase the reliability of the insertion of the conductive-line terminal 162 of the fusible resistor 16, a distance between the metal springs 21 is gradually decreased along the inputting direction of the conductive-line terminal 162 of the fusible resistor 16. Accordingly, even when the conductive-line terminal 162 of the fusible resistor 16 is skewed during the plug-in operation, the conductive-line terminal 162 of the fusible resistor 16 may still be inserted and clamped by the metal springs 21 due to the guiding function of the inclined metal springs 21.

In addition, in order to not bend the conductive-line terminal 162 of the fusible resistor 16 during the plug-in operation, the central axis of the guiding hole 22 is aligned with the middle position between the pair of metal springs 21. Accordingly, when the conductive-line terminal 162 of the fusible resistor 16 is outputted from the exit 222 of the guiding hole 22, the conductive-line terminal 162 of the fusible resistor 16 may locate at the clamping position of the metal springs 21.

According to some embodiments, the conductive-line terminal 162 of the fusible resistor 16 is connected to the connector 20 after the plug-in operation, and the conductive-line terminal 163 of the fusible resistor 16 is connected to the conductive rivet 15 after the assembly process. Therefore, in order to manufacture the fusible resistor 16 by an automation process for increasing the reliability of assembly, the length of the conductive-line terminal 162 of the fusible resistor 16 is shorter than the length of conductive-line terminal 163 of the fusible resistor 16. The conductive-line terminal 162 of the fusible resistor 16 is also harder than the conductive-line terminal 163 of the fusible resistor 16. When the conductive-line terminal 162 is shorter and harder, e.g. when the material of the conductive-line terminal 162 is composed of copper-clad steel, the conductive-line terminal 162 is more easily to insert to a middle position between the metal springs 21. On the other hand, when the conductive-line terminal 163 is longer and softer, e.g. when the material of the conductive line of the plug terminal is composed of copper, the conductive-line terminal 163 is more easily to be assembled or mounted with the conductive rivet 15. In other words, the two conductive-line terminals 162 and 163 of the fusible resistor 16 may be composed of different materials.

FIG. 7 is a diagram illustrating a riveting punch 30 riveting an inner wall of the metal cup 141 of the LED lighting device in accordance with some embodiments. During the assembly process, the riveting punch 30 is arranged to face the inner wall of the metal cup 141 on top. Meanwhile, the light-source board 12 is placed between the inner wall of the metal cup 141 and the riveting punch 30. Then, the riveting punch 30 rivets the portion of inner wall of the metal cup 141 that is higher than the light-source board 12. The metal cup 141 is deformed to contact the conductive layer 121 of the light-source board 12. It is noted that, the riveting punch 30 may press the conductive layer 121 of the light-source board 12 to deform the metal cup 141. Accordingly, the conductive rivet 15, the fusible resistor 16, the light-source board 12, and the metal cup 141 may be electrically connected with each other. Then, the bulb shell 11 (not shown in FIG. 7) covers the top of the lamp holder 13 to accomplish the whole structure of the LED lighting device.

Briefly, according to the present embodiment, the conductive-line terminal 162 and the conductive-line terminal 163 of the fusible resistor 16 are connected to the light-source board 12 and the conductive rivet 15 without using the wielding process. The conductive rivet 15, the fusible resistor 16, the light-source board 12, and the metal cup 141 are electrically connected with each other without using the wielding process. The components of the LED lighting device are mostly assembled by mechanical operation. Therefore, the complexity of the assembly process of the LED lighting device may be reduced, and the LED lighting device may be manufactured by an automation process to reduce cost.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

1. An LED (Light Emitting Diode) lighting device, comprising:
a bulb shell;
a light-source board, having a connector, the light-source board disposed in the bulb shell for generating optical light;
a light bulb adapter electrically connected to the light-source board;
a conductive rivet, disposed on a bottom of the LED light device, wherein the conductive rivet is insulated from a bottom of the light bulb adapter; and
a fusible resistor, having a first conductive-line terminal clamped by the connector and a second conductive-line terminal coupled to the conductive rivet.

2. The LED lighting device of claim 1, wherein the fusible resistor is orthogonally coupled to the light-source board.

3. The LED lighting device of claim 1, wherein the connector comprises:
at least one metal spring, disposed in a middle of the connector, for clamping the first conductive-line terminal of the fusible resistor.

4. The LED lighting device of claim 1, wherein the first conductive-line terminal and the second conductive-line terminal of the fusible resistor are formed by a first conductive line and a second conductive line respectively, and the first conductive line is shorter and harder than the second conductive line.

5. The LED lighting device of claim 1, further comprising:
a lamp holder, arranged to hold the bulb shell; and
wherein the light bulb adapter is installed on a bottom of the lamp holder;
wherein the conductive rivet is installed on a bottom of the light bulb adapter, and the fusible resistor penetrates the light bulb adapter and the lamp holder to reach the light-source board from the conductive rivet.

6. The LED lighting device of claim 5, wherein the lamp holder comprises:
an intra-cavity connection, configured to have a guiding column;
wherein the guiding column is arranged to axially cut-through the intra-cavity connection to form a guiding channel in the intra-cavity connection, and the fusible resistor is disposed in the guiding channel.

7. The LED lighting device of claim 6, wherein the first conductive-line terminal of the fusible resistor is extended to protrude an end of the guiding channel for connecting the light-source board, the second conductive-line terminal of the fusible resistor is extended to protrude another end of the guiding channel for connecting the conductive rivet.

8. The LED lighting device of claim 6, wherein the guiding channel comprises:
a resistor receiving chamber, forming on a first end of the guiding channel that is faced to the light-source board; and
a guiding chamber, forming on a second end of the guiding channel that is faced to the conductive rivet;
wherein a radial size of the resistor receiving chamber is greater than the guiding chamber, and a connecting boundary of the resistor receiving chamber and the guiding chamber forms a step.

9. The LED lighting device of claim 8, wherein the fusible resistor further comprises a fusible element formed between the first conductive-line terminal and the second conductive-line terminal, the fusible element is disposed in the resistor receiving chamber, and the fusible element is attached on the step.

10. The LED lighting device of claim 5, further comprising:
a metal cup, embedded on an inner wall of the lamp holder for installing the light source board on the lamp holder;
wherein an inner wall of the metal cup, which is above the light-source board, is riveted such that the metal cup is deformed for contacting a conductive layer of the light-source board.

11. The LED lighting device of claim 1, wherein the connector comprises:
a pair of metal springs; and
a cut-through channel, formed along an inputting direction of the first conductive-line terminal of the fusible resistor, an end of the cut-through channel that is faced to the fusible resistor is arranged to have a guiding hole, and an exit of the guiding hole is faced to the pair of metal springs.

12. The LED lighting device of claim 11, wherein an entry of the guiding hole that is faced to the fusible resistor is greater than the exit that is faced to the pair of metal springs.

13. The LED lighting device of claim 11, wherein the pair of metal springs are a pair of opposite clamping metal springs, the first conductive-line terminal of the fusible resistor is clamped between the pair of opposite clamping metal springs for electrically connecting the light-source board.

14. The LED lighting device of claim 11, wherein the pair of metal springs are disposed in the cut-through channel, a pair of first terminals of the pair of metal springs are fixed, a pair of second terminals of the pair of metal springs are arranged to extend oppositely to approach each other, a distance between the pair of metal springs is gradually decreased along the inputting direction of the first conductive-line terminal of the fusible resistor.

15. The LED lighting device of claim 11, wherein the central axis of the guiding hole is aligned with a middle position between the metal springs.

16-20. (canceled)
